(19) United States
(12) Patent Application Publication
(10) Pub. No.: US 2001/0023969 A1
(43) Pub. Date: Sep. 27, 2001

(54) Integrated circuit and method of manufacturing same

(76) Inventors: Bernhard Lustig, Muenchen (DE); Martin Franosch, Muenchen (DE)

Correspondence Address: SCHIFF HARDIN & WAITE, 6600 SEARS TOWER, 233 S WACKER DR, CHICAGO, IL, 60606-6473, US

(21) Appl. No.: 09/846,822

(22) Filed: Apr. 30, 2001

Related U.S. Application Data
(62) Division of application No. 09/409,499, filed on Sep. 30, 1999.

(30) Foreign Application Priority Data
Sep. 30, 1998 (DE) 198 45 066.4

(51) Int. Cl. H01L 21/8238; H01L 29/76; H01L 29/94; H01L 31/062; H01L 31/113; H01L 31/119

(52) U.S. Cl. 257/402

(57) ABSTRACT

An integrated circuit arrangement having two NMOS transistors with different cut off voltages and two PMOS transistors with different cut off voltages. Channel regions of the NMOS transistors exhibit the same dopant concentration. The analogous case applies to the PMOS transistors. The different cut off voltages are achieved by different chemical compositions of the gate electrodes of the transistors. Preferably, the chemical compositions of the gate electrodes of respectively one of the NMOS transistors and one of the PMOS transistors thereby coincide. Si₁₋ₓGeₓ with 0≦x≦1 is suitable as a material for the gate electrodes. The transistors preferably form pairs with transistors complementary to one another that exhibit the same cut off voltages. Given a dopant concentration of the channel regions of the NMOS transistors that is approximately 1.5 times greater than a dopant concentration of the channel regions of the PMOS transistors, the value of x amounts, for example, to 0.47 for respectively one of the transistors in each of the pairs or zero for respectively another of the transistors in each of the two pairs.

### BACKGROUND OF THE INVENTION

The present invention is directed to an integrated circuit arrangement and a method for the manufacture thereof.

Semiconductor components of electronic circuit arrangements are being increasingly integrated on a single chip. Such a circuit arrangement is referred to as an integrated circuit arrangement. When an integrated circuit arrangement comprises, for example, an analog high-frequency circuit and a digital logic circuit, then some of the semiconductor components are transistors with various cut-off voltages. The transistors of the high-frequency circuit preferably comprise low cut-off voltages so that they can be switched faster. The transistors of the logic circuit preferably exhibit high cut-off voltages so that a lower power consumption is enabled in the non-conductive condition of the transistors and, thus, a service life of a battery can, for example, be effectively lengthened.

A SRAM cell arrangement having a number of NMOS transistors that exhibit different cut-off voltages and having a number of PMOS transistors that exhibit different cut-off voltages is known, for example, from T. Yabe et al., “High-speed and low-standby-power circuit design of 1 to 5 V operating 1 Mb Full CMOS SRAM”, 1993 Symp. On VLSI Circuits, Digest of Technical Papers, p. 107.

Different cut-off voltages are usually defined in semiconductor fabrication by the height of a dopant concentration of a channel region of the transistor.

P.-E. Hellberg et al., “Work Function of Boron-Doped Polycrystalline SiₓGe₁₋ₓ Films”, IEEE Electron Device Letters, Vol. 18, No. 9 (1997), discloses that gate electrodes of a PMOS transistor composed of p-doped SiₓGe₁₋ₓ and of an NMOS transistor should contain as much germanium as possible so that gate electrodes of the same material can be employed, that symmetrically drive both transistors so that the transistors can exhibit the same cut-off voltages in terms of amount.

### SUMMARY OF THE INVENTION

It is an object of the present invention to provide an integrated circuit arrangement that comprises PMOS transistors with different cut-off voltages and NMOS transistors with different cut-off voltages that can be manufactured with lower process outlay compared to the prior art and that exhibits better electrical properties. Further, a method for the manufacture thereof is disclosed.

This object is achieved in accordance with the invention in an integrated circuit arrangement having a first NMOS transistor that exhibits a first cut off voltage; a second NMOS transistor that exhibits a second cut off voltage that differs from the first cut off voltage; a first PMOS transistor that exhibits a third cut off voltage; and a second PMOS transistor that exhibits a fourth cut off voltage that is different from the third cut off voltage, whereby the channel regions of the first NMOS transistor and of the second NMOS transistor exhibit the same dopant concentration, whereby channel regions of the first PMOS transistor and of the second PMOS transistor exhibit the same dopant concentration, whereby a chemical composition of a gate electrode of the first NMOS transistor and a chemical composition of a gate electrode of the second NMOS transistor differ from one another, and whereby a chemical composition of a gate electrode of the first PMOS transistor and a chemical composition of a gate electrode of the second PMOS transistor differ from one another.

The object is also achieved in accordance with the invention in a method for manufacturing an integrated circuit, whereby a first NMOS transistor and a second NMOS transistor are produced such that their channel regions exhibit the same dopant concentration. Further, a first PMOS transistor and a second PMOS transistor are produced such that their channel regions exhibit the same dopant concentration. A gate electrode for the first NMOS transistor and a gate electrode for the second NMOS transistor are produced, whereby the gate electrodes exhibit different chemical compositions, so that the first NMOS transistor exhibits a first cut off voltage and the second NMOS transistor exhibits a second cut off voltage that differ from one another. A gate electrode for the first PMOS transistor and a gate electrode for the second PMOS transistor are produced, whereby the gate electrodes exhibit different chemical compositions, so that the first PMOS transistor exhibits a third cut off voltage and the second PMOS transistor exhibits a fourth cut off voltage that differ from one another.

In contrast to integrated circuit arrangement having traditional CMOS transistors, in the present invention, different cut off voltages are not set by the selection of different dopant concentrations of the channel regions but by the selection of different chemical compositions of the gate electrodes. Since the dopant concentration is not the only thing defining the cut off voltage, it can be selected independently of the cut off voltage such that the mobility of the charge carriers are optimized vis-a-vis short-channel effects. The inventive circuit arrangement, consequently, can exhibit better electrical properties.

When different cut off voltages are set by selection of different dopant concentrations of the channel regions of the CMOS transistors, then a separate, masked implantation must be implemented for each channel region of PMOS transistors that exhibit different cut off voltages. The same is true of NMOS transistors with different cut off voltages. Compared thereto, the invention enables the production of the channel regions of all NMOS transistors—due to their identical dopant concentrations—with only one masked implantation, this meaning low process outlay. The same is true of the PMOS transistors.

An increase in the dopant concentration in channel regions of PMOS and NMOS transistors effects a decrease of short-channel effects and a lowering of the mobility of charge carriers. A dopant concentration of the channel regions of the transistors essentially between 10¹⁷ cm⁻³ and 10¹⁸ cm⁻³ is advantageous as compromise.

Given the same dopant concentrations of the channel regions, NMOS transistors exhibit a higher mobility of the charge carriers than the PMOS transistors. In order to assure an appropriately high mobility of the charge carriers, the dopant concentration of the PMOS transistors is consequently preferably lower than that of the NMOS transistors. The channel regions of the NMOS transistors are, for example, doped approximately 1.5 through 2 times higher than the channel regions of the PMOS transistors. The NMOS transistors are optimized in view of low short-channel effects.

It is advantageous for process simplification when, apart from dopings, the chemical composition of the gate electrode of the first NMOS transistor coincides with the chemical composition of the gate electrode of the first PMOS transistor. An analogous case applies to the gate electrodes of the second NMOS transistor and of the second PMOS transistor. In this case, an initial layer can be applied and structured for producing the gate electrode of the second NMOS transistor and the gate electrode of the second PMOS transistor, so that said gate electrodes are produced simultaneously, as a result whereof the process outlay is low. The analogous case applies to the first NMOS transistor and the first PMOS transistor for which a further layer having a different material is produced.

The initial layer is initially preferably structured such that it is removed from regions of the first NMOS transistor and of the first PMOS transistor. Subsequently, the further layer is deposited and can be structured such that it is removed from the initial layer. The initial layer and the further layer are structured with a gate mask for producing the gate electrodes of the four transistors.

Source/drain regions of the transistors can ensue by implantation after production of the gate electrodes, so that the gate electrodes are doped with the same conductivity type as the source/drain regions. In this case, the gate electrode of the first NMOS transistor is doped with a different conductivity type than the gate electrode of the first PMOS transistor. The analogous case applies to the second NMOS transistor and the second PMOS transistor.

Si₁₋ₓGeₓ with 0≦x≦1 is suitable as material for the gate electrodes, since this material can be easily integrated into traditional semiconductor manufacture, particularly since germanium does not act as dopant in silicon and vice versa.

Transistor pairs with different cut off voltages wherein the transistors of a pair exhibit the same cut off voltages but are complementary to one another (see the aforementioned article by T. Yabe et al.), are employed particularly in the logic circuit and also in other circuit arrangements. It is therefore within the scope of the invention when the first NMOS transistor and the second PMOS transistor form a first transistor pair, and the second NMOS transistor and the first PMOS transistor form a second transistor pair. In this case, the first cut off voltage is equal to the fourth cut off voltage and the second cut off voltage is equal to the third cut off voltage. To that end, the value of x of the gate electrode of the first NMOS transistor or of the first PMOS transistor and the value of x of the gate electrode of the second NMOS transistor or of the second PMOS transistor are matched to one another dependent on the selected dopant concentration of these transistors. This development of the invention is based on the physical effect that the cut off voltage in PMOS transistors with p-doped gate electrodes becomes all the higher the higher the value of x is, whereas, by contrast, the cut off voltage is lowered given NMOS transistors with n-doped gate electrodes.

The invention enables the manufacture of such transistor pairs with low process outlay since a low number of masks is required. A well mask is provided for the implantation of the channel regions of all NMOS transistors and another well mask is provided for the implantation of the channel regions of all PMOS transistors. Two masks for structuring the layers for their gate electrodes are provided for the two transistor pairs. With the one mask, the layer of Si₁₋ₓGeₓ is structured with a first value of x in order to remove the initial layer from regions of the remaining transistors, so that only the gate electrode of the second NMOS transistor and the gate electrode of the second PMOS transistor are produced from this initial layer in the production of the gate electrodes. With the other mask, the further layer of Si₁₋ₓGeₓ is structured with a second value of x in order to remove the further layer from the initial layer, i.e. from regions of the second NMOS transistor and of the second PMOS transistor, so that the gate mask can be generated on a planar surface and diffusion between the layers is avoided. When producing the gate electrodes, only the gate electrode of the first NMOS transistor and the gate electrode of the first PMOS transistor arise from the further layer. Only two additional masks, namely masks for structuring layers of Si₁₋ₓGeₓ with two different values of x, are required for two additional transistor pairs. By contrast thereto, two additional transistor pairs require four additional masks when the cut off voltages are set via the dopant concentrations, namely well masks, since each channel region of the four transistors must be separately implanted.

The value of x of the gate electrode of the first NMOS transistor or of the first PMOS transistor preferably lies at zero or slightly above. A value up to 0.1 likewise lies within the scope of the invention. The value of x of the gate electrode of the second NMOS transistor or of the second PMOS transistor preferably amounts to between 0.2 and 0.6, for example 0.47.

The circuit arrangement can be an SRAM cell arrangement, whereby the four transistors are part of one of its memory cells.

The circuit arrangement can comprise a DRAM cell arrangement, whereby the first NMOS transistor and the second PMOS transistor are parts of the periphery of the DRAM cell arrangement. The second NMOS transistor and the first PMOS transistor preferably lie outside the DRAM cell arrangement in an analog field and are part of a time-critical circuit. Memory cells of the DRAM cell arrangement respectively comprise at least one selection transistor (cell transistor) that is preferably a further NMOS transistor whose channel region exhibits the same dopant concentration as the channel regions of the first NMOS transistor and of the second NMOS transistor. As a result thereof, the channel regions of the selection transistors can be produced simultaneously with the channel regions of the first NMOS transistor and of the second NMOS transistor, this denoting a low process outlay. The cut off voltage of the selection transistor is preferably especially high. A gate electrode of the selection transistor therefore comprises Si₁₋ₓGeₓ with x≧0.95. The selection transistor can also be a PMOS transistor.

The selection transistors can be respectively connected to a storage capacitor, to a word line and to a bit line. Alternatively, a number of selection transistors are interconnected, so that a memory cell comprises a number of transistors, for example three.

It lies within the scope of the invention to provide the gate electrodes of the first NMOS transistor, of the second NMOS transistor, of the first PMOS transistor and of the second PMOS transistor with thin spacers of polysilicon. In this ways evaporation of germanium during following process steps with high temperature can be suppressed.

Spacers of SiO₂ or silicon nitride can be deposited over the spacers of polysilicon in order to keep an under-diffusion of the gate electrodes from the source/drain regions low. Over and above this, sidewalls of the gate electrodes are passivated by the spacers.

It lies within the scope of the invention that the circuit arrangement comprises additional CMOS transistors whose channel regions exhibit different dopant concentrations than the channel regions of the first NMOS transistor and of the first PMOS transistor.

These and other features of the invention(s) will become clearer with reference to the following detailed description of the presently preferred embodiments and accompanied drawings.

### DESCRIPTION OF THE DRAWINGS

FIG. 1 is a cross-section through three regions of a substrate after insulating structures, wells, a gate dielectric, a nucleation layer and a structured, first layer are produced.

FIG. 2 is the cross-section from FIG. 1 after a structured, second layer is produced.

FIG. 3 is the cross-section from FIG. 2 after a third layer is produced.

FIG. 4 is the cross-section from FIG. 3 after a gate electrode of a first NMOS transistor, a gate electrode of a first PMOS transistor, a gate electrode of a second NMOS transistor, a gate electrode of a second PMOS transistor, source/drain regions of the first NMOS transistor, of the second NMOS transistor, of the first PMOS transistor and of the second PMOS transistor and storage capacitors, word lines and bit lines are produced.

### DETAILED DESCRIPTION OF THE PRESENTLY PREFERRED EMBODIMENTS

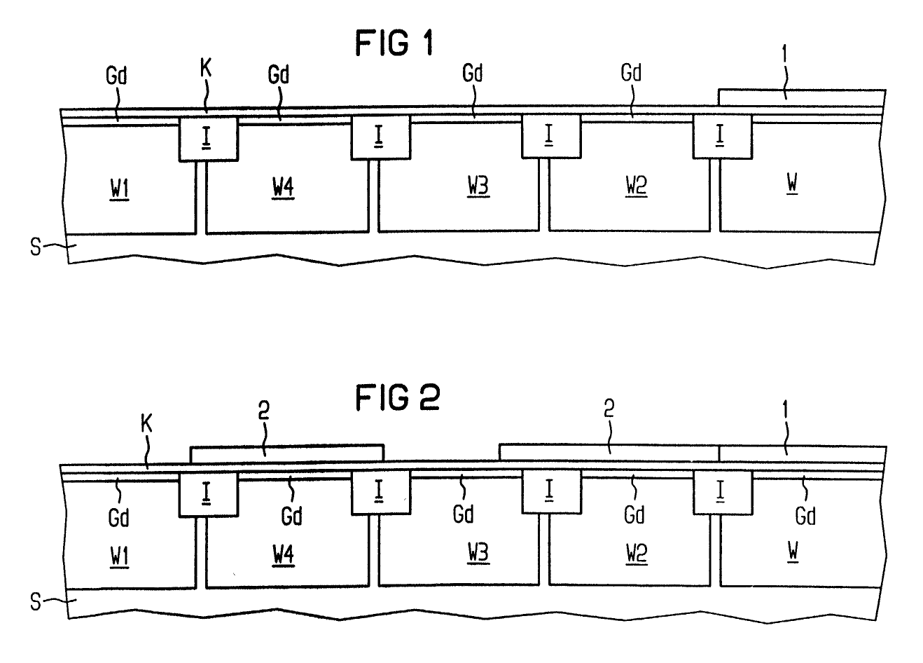

Referring to FIG. 1, in an embodiment, a substrate S of silicon is provided as an initial material. According to the prior art, insulating structures I that surround transistors to be produced are generated in trenches.

With the assistance of a first well mask (not shown), a first p-doped well W1 for a first NMOS transistor is produced by a first implantation in a first region of the substrate S and a second p-doped well W2 for a second NMOS transistor is produced in a second region of the substrate S. The dopant concentration of the first well W1 and of the second well W2 amounts to approximately 8*10¹⁷ cm⁻³.

With the assistance of a second well mask (not shown), a first n-doped well W3 for a first PMOS transistor is produced by a second implantation in the second region of the substrate S, a second n-doped well W4 for a second PMOS transistor is produced in the first region of the substrate S, and n-doped wells W for selection transistors are produced in a third region of the substrate S. The dopant concentration of the third well W3, of the fourth well W4 and of the wells W for the selection transistors amounts to approximately 6*10¹⁷ cm⁻³.

By thermal oxidation, an approximately 4 nm thick gate dielectric Gd is produced over the doped wells W1, W2, W3, W4, W. Subsequently, an approximately 5 nm thick nucleation layer K of silicon is deposited.

A first layer 1 of polycrystalline Si_{0.05}Ge_{0.95} is deposited to a thickness of approximately 50 nm and is etched with the assistance of a first mask (not shown). The first mask covers the wells W for the selection transistors. The deposition of the polycrystalline Si_{0.05}Ge_{0.95} ensues at a temperature between 300° C. and 600° C. and a process pressure of approximately 10 Torr through 650 Torr. A process gas comprises germanium and silane or disilane. The nucleation layer K facilitates the deposition of the polycrystalline Si_{0.05}Ge_{0.95} without influencing cut off voltages of the selection transistors.

Referring to FIG. 2, subsequently, an approximately 50 nm thick second layer 2 of polycrystalline Si_{0.53}Ge_{0.47} is deposited and etched with the assistance of a second mask (not shown). The second mask covers the second well W2 and the fourth well W4. The deposition of the polycrystalline S_{0.53}Ge_{0.47} ensues at a temperature between 300° C. and 600° C. and a process pressure of approximately 10 Torr through 650 Torr. A process gas comprises germanium and silane or disilane. The nucleation layer K facilitates the deposition of the polycrystalline SiO_{0.53}Ge_{0.47} without influencing cut off voltages of the transistors.

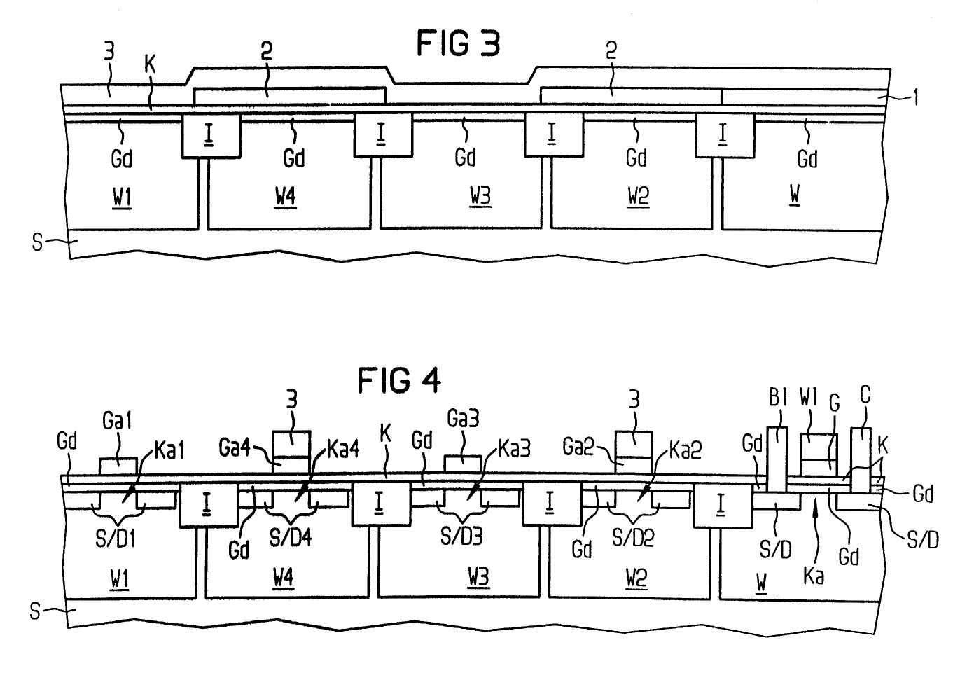

Referring to FIG. 3, a third layer 3 is produced by deposition of polycrystalline silicon to a thickness of approximately 150 nm.

Referring to FIG. 4, the third layer is deposited and structured with the assistance of a third mask (not shown). The third mask covers a region over the first well W1, so that a gate electrode Gal of the first NMOS transistor is produced over the first well W1 from the third layer 3. The third mask covers a region over the second well W2, so that a gate electrode Ga2 of the second NMOS transistor is produced over the second well W2 from the second layer 2. The third mask covers a region over the third well W3, so that a gate electrode Ga3 of the first PMOS transistor is produced over the third well W3 from the third layer 3. The third mask covers a region over the fourth well W4, so that a gate electrode Ga4 of the second PMOS transistor is produced over the fourth well W4 from the second layer 2. The third mask covers regions above the well W, so that word lines W1 are produced from the third layer 3 and gate electrodes G of the selection transistors over the well W are produced from the first layer 1.

An implantation with n-doping ions is implemented with the assistance of a fourth mask (not shown) that is arranged over the third well W3, the fourth well W4 and the wells W for the selection transistors, so that source/drain regions S/D1 of the first NMOS transistor and source/drain regions S/D2 of the second NMOS transistor are produced. The gate electrode Ga1 of the first NMOS transistor and the gate electrode Ga2 of the second NMOS transistor are thereby n-doped.

With the assistance of a fifth mask (not shown) that is arranged over the first well W1 and the second well W2, an implantation with p-doping ions is implemented, so that source/drain regions S/D3 of the first PMOS transistor, source/drain regions S/D4 of the second PMOS transistor and source/drain regions S/D of the selection transistors are produced. The gate electrode Ga3 of the first PMOS transistor, the gate electrode Ga4 of the second PMOS transistor and the gate electrodes G of the selection transistors are thereby p-doped.

Channel regions Ka1, Ka2, Ka3, Ka4, Ka of the transistors are parts of the wells W1, W2, W3, W4, W arranged under the pertaining gate electrodes Ga1, Ga2, Ga3, Ga4 that lie between the pertaining source/drain regions S/D1, S/D2, S/D3, S/D4, S/D. Widths of the gate electrodes Ga1, Ga2, Ga3, Ga4 and, consequently, the channel lengths of the first NMOS transistor, of the second NMOS transistor, of the first PMOS transistor and of the second PMOS transistor amount to approximately 130 nm.

Storage capacitors C are produced that are respectively connected to one of the selection transistors. The selection transistors are connected to word lines W1 and bit lines B1, so that a DRAM memory is produced. The storage capacitors C, the word lines W1, and the bit lines B1 are schematically shown in FIG. 4.

The first NMOS transistor and the second PMOS transistor form a transistor pair, exhibit a cut off voltage of approximately 0.4 V, and are part of a periphery of the DRAM memory. The second region of the substrate S lies outside the DRAM memory in an analog field. The second NMOS transistor and the first PMOS transistor form a further transistor pair, exhibit a cut off voltage of approximately 0.2 V, and are part of a time-critical circuit. In the third region of the substrate S, memory cells of the DRAM memory that respectively comprise one of the selection transistors and one of the storage capacitors are arranged.

Many variations of the exemplary embodiment that likewise lie within the scope of the invention are conceivable. Thus, dimensions of the gate electrodes and dopant concentrations of the wells and source/drain regions as well as the mixing ratio of silicon and germanium in the gate electrodes can thus be adapted to respective requirements. Further CMOS transistor pairs that respectively exhibit different cut off voltages can be produced.

The gate electrodes can be provided with thin spacers of polysilicon. In this way, evaporation of germanium during following process steps with high temperatures can be suppressed.

Spacers of SiO₂ or silicon nitride can be deposited over the spacers of polysilicon. The spacers of SiO₂ prevent the source/drain regions of the transistors from extending laterally under the appertaining gate electrodes due to diffusion. Over and above this, sidewalls of the gate electrodes are passivated by the spacers.

Although modifications and changes may be suggested by those of ordinary skill in the art, it is the intention of the inventors to embody within the patent warranted hereon all changes and modifications as reasonably and properly come within the scope of their contribution to the art.

We claim as our invention:

1. An integrated circuit arrangement comprising:
a first NMOS transistor including a first channel region having a dopant concentration, and a first gate electrode having a chemical composition, said first NMOS transistor exhibiting a first cut off voltage;
a second NMOS transistor including a second channel region having a same dopant concentration as said first channel region, and a second gate electrode having a different chemical composition from said first gate electrode, said second NMOS transistor exhibiting a second cut-off voltage different from said first cut off voltage;
a first PMOS transistor including a third channel region having a dopant concentration, and a third gate electrode having a chemical composition, said first PMOS transistor exhibiting a third cut off voltage; and
a second PMOS transistor including a fourth channel region having a same dopant concentration as said third channel region, and a fourth gate electrode having a different chemical composition from said third gate electrode, said second PMOS transistor exhibiting a fourth cut-off voltage different from said third cut off voltage.

2. The circuit arrangement according to claim 1, wherein, apart from a doping of said first gate electrode and said third gate electrode, said first gate electrode of said first NMOS transistor has a same chemical composition as said third gate electrode of said first PMOS transistor; and wherein apart from a doping of said second gate electrode and said fourth gate electrode, said second gate electrode of said second NMOS transistor has a same chemical composition as said fourth gate electrode of said second PMOS transistor.

3. The circuit arrangement according to claim, wherein said first gate electrode, said second gate electrode, said third gate electrode and said fourth gate electrode further comprise Si₁₋ₓGeₓ with 0≦x≦1, said value of x being independent for each of said gate electrodes.

4. The circuit arrangement according to claim 3,
wherein a first value of x of said first gate electrode of said first NMOS transistor and of said third gate electrode of said first PMOS transistor is smaller than a second value of x of said second gate electrode of said second NMOS transistor and of said fourth gate electrode of said second PMOS transistor;
wherein said dopant concentration of said first channel region and said second channel region and said dopant concentration of said third channel region and said fourth channel region are selected such that short-channel effects are slight given a good mobility of charge carriers of said first and second NMOS transistors and said first and second PMOS transistors; and
wherein said first value of x and said second value of x are matched to one another for said first cut off voltage to be equal to said fourth cut off voltage and said second cut off voltage to be equal to said third cut off voltage.

5. The circuit arrangement according to claim 3,
wherein said dopant concentration of said first and second channel regions is a maximum of twice as high as said dopant concentration of said third and fourth channel regions;
wherein said first value of x of said first gate electrode and of said third gate electrode is between 0 and 0.1; and
wherein said second value of x of said second gate electrode and of said fourth gate electrode is between 0.2 and 0.6.

6. The circuit arrangement according to claim 4, further comprising:
a DRAM cell arrangement having memory cells respectively including at least one selection transistor, said selection transistor being a further transistor selected from the group consisting of NMOS transistors and PMOS transistors and having a fifth channel region having a dopant concentration selected from the group consisting of said dopant concentration of said first and second channel regions and said dopant concentration of said third and fourth channel regions, said selection transistor further having a fifth gate electrode containing Si₁₋ₓGeₓ with x≧0.9.

7. A method for manufacturing an integrated circuit arrangement, said method comprising the steps of:
producing a first NMOS transistor including a first channel region having a dopant concentration, and a first gate electrode having a chemical composition, said first NMOS transistor exhibiting a first cut off voltage;
producing a second NMOS transistor including a second channel region having a same dopant concentration as said first channel region, and a second gate electrode having a different chemical composition from said first gate electrode, said second NMOS transistor exhibiting a second cut-off voltage different from said first cut off voltage;
producing a first PMOS transistor including a third channel region having a dopant concentration, and a third gate electrode having a chemical composition, said first PMOS transistor exhibiting a third cut off voltage; and
producing a second PMOS transistor including a fourth channel region having a same dopant concentration as said third channel region, and a fourth gate electrode having a different chemical composition from said third gate electrode, said second PMOS transistor exhibiting a fourth cut-off voltage different from said third cut off voltage.

8. The method according to claim 7, further comprising the steps of:
simultaneously producing a first p-doped well and a second p-doped well, said first channel region of said first NMOS transistor being produced from said first p-doped well, said second channel region of said second NMOS transistor being produced from said second p-doped well;
simultaneously producing a third n-doped well and a fourth n-doped well, said third channel region of said first PMOS transistor being produced from said third n-doped well, said fourth channel region of said second PMOS transistor being produced from said fourth n-doped well;
applying and structuring an initial layer for simultaneously producing said second gate electrode and said fourth gate electrode; and
applying and structuring a further layer for simultaneously producing said first gate electrode and said third gate electrode.

9. The method according to claim 7,
wherein said initial layer comprises Si₁₋ₓGeₓ with 0≦x≦1, said value of x being independent for each gate electrode; and
wherein said further layer comprises Si₁₋ₓGeₓ with 0≦x≦1, said value of x being independent for each gate electrode.

10. The method according to claim 9, further comprising the steps of:
wherein a first value of x of said first gate electrode and of said third gate electrode is smaller than a second value of x of said second gate electrode and of said fourth gate electrode;
wherein said dopant concentration of said first channel region and said second channel region and said dopant concentration of said third channel region and said fourth channel region are selected such that short-channel effects are slight given a good mobility of charge carriers of said first and second NMOS transistors and said first and second PMOS transistors; and
wherein said first value of x and said second value of x are matched to one another for said first cut off voltage to be equal to said fourth cut off voltage and said second cut off voltage to be equal to said third cut off voltage.

11. The method according to claim 10,
wherein said dopant concentration of said first and second channel regions is a maximum of twice as high as said dopant concentration of said third and fourth channel regions;
wherein said first value of x of said first gate electrode and of said third gate electrode is between 0 and 0.1; and
wherein said second value of x of said second gate electrode and of said fourth gate electrode is between 0.2 and 0.6.

12. The method according to claim 10, further comprising the steps of:
producing a DRAM memory in a same substrate as said first and second NMOS transistors and said first and second PMOS transistors; and
producing memory cells for said DRAM memory, said memory cells respectively comprising at least one selection transistor, said selection transistor being a further transistor selected from the group consisting of NMOS transistors and PMOS transistors and having a fifth channel region having a dopant concentration selected from the group consisting of said dopant concentration of said first and second channel regions and said dopant concentration of said third and fourth channel regions, said selection transistor further having a fifth gate electrode containing Si₁₋ₓGeₓ with x≧0.9.
